(19) United States
(12) Patent Application Publication
(10) Pub. No.: US 2014/0169059 A1
(43) Pub. Date: Jun. 19, 2014

(54) FUSE REPAIR DEVICE

(71) Applicant: SK HYNIX INC., Gyeonggi-do (KR)

(72) Inventors: Yong-Ho KONG, Gyeonggi-do (KR); Je-Yoon KIM, Gyeonggi-do (KR)

(73) Assignee: SK HYNIX INC., Gyeonggi-do (KR)

(21) Appl. No.: 13/846,055

(22) Filed: Mar. 18, 2013

(30) Foreign Application Priority Data
Dec. 17, 2012 (KR) 10-2012-0147507

(51) Int. Cl. G11C 17/16

(52) U.S. Cl. CPC G11C 17/16
USPC 365/96

(57) ABSTRACT

A fuse repair device may include a first fuse circuit configured to store a first portion out of a failed address, a second fuse circuit configured to store a multipurpose information or a second portion of the failed address, an enable control circuit configured to provide a first enable signal to enable the second fuse unit based on a first control signal, a switch control circuit configured to provide a second enable signal to enable the second fuse unit based on a second control signal, a repair control signal generation circuit configured to compare data stored in the first fuse circuit and the second fuse circuit with an input address, and generate a repair control signal based on the first enable signal and the second enable signal, and a multipurpose control signal generation circuit configured to generate a multipurpose control signal to control operations different from a repair operation.

### CROSS-REFERENCE TO RELATED APPLICATIONS

The present application claims priority of Korean Patent Application No. 10-2012-0147507, filed on Dec. 17, 2012, which is incorporated herein by reference in its entirety.

### BACKGROUND

1. Field

Exemplary embodiments of the present invention relate to a semiconductor design technology, and more particularly, to a fuse repair circuit.

2. Description of the Related Art

A semiconductor device having a memory includes a fuse circuit to store an address information for a repair or multipurpose information, e.g., command set information, mode register set information, test mode information and the like.

A fuse included in the fuse circuit stores the address information or the multipurpose information through a fuse programming. When the fuse gets stressed by a laser beam or an electrical stress, an electrical coupling characteristic of the fuse is changed, and an electrical resistance value of the fuse is changed. The fuse is programmed using the change of the electrical coupling characteristic.

For reference, a laser blowing-type fuse that cuts a coupling state of the fuse by the laser beam is generally indicated as a physical fuse type, which is performed at a wafer level before packaging. An electrical method is used in the package level. The fuse capable of being programmed at the package level is generally indicated as ‘an electrical fuse’. This represents that the programming is performed by changing an electrical coupling state of the fuse through the electrical stress. The electrical fuse may be classified into an anti-type fuse and a blowing-type fuse. The anti-type fuse changes the state of the fuse from open to short. The blowing-type fuse changes the state of the fuse from short to open. These fuses are selectively used according to characteristics and size of the semiconductor device.

In case of the anti-type fuse, it is referred to as ‘rupture’ that the programming is performed by changing the state of the fuse from open to short. For example, a metal oxide semiconductor (MOS) anti-type fuse using a metal oxide semiconductor field effect transistor (MOSFET) having a thin gate oxide is widely used. The state of both ends of the thin gate oxide is changed from open to short by supplying a voltage to the both ends of the thin gate oxide through ‘rupture’. Thus, the MOS anti-type fuse stores information of one bit having a ruptured short state or a non-ruptured open state.

In general, the fuse circuit includes a plurality of fuse sets for storing a lot of information. Each fuse set includes a plurality of fuse units for storing and outputting information of one bit and an enable fuse unit for indicating whether the information is programmed on the fuse set. The enable fuse unit provides information the programming state of the fuse set. The number of fuse sets and fuse units included in the fuse circuit are determined according to the number of information and the bit size of the information.

Meanwhile, a high integration of a semiconductor device has developed. Especially, a capacity of a memory device of the semiconductor device increases due to the high integration. The increase of the capacity of the memory device represents that the number of memory cells included in a chip increases. The number of failed memory cells increases as the number of memory cells increases. In case that a failed memory cell occurs in normal memory cells, a redundant memory cell is prepared to replace the failed memory cell. It is referred to as ‘a repair operation’ that the failed memory cell is replaced by the redundant memory cell.

More specifically, a failed address that indicates a location of a failed memory cell is detected using a semiconductor test device. The failed address is stored by programming a fuse included in a repair fuse circuit. After the failed address is stored in the repair fuse circuit, if an input address that indicates the failed memory cell is input, it is determined that the failed address stored in the repair address circuit is same as the input address. Thus, a repair operation is performed as described below. That is, an access to the failed memory cell is cut off by inactivating a failed path that is an access to the failed memory cell, and an access to the redundant memory cell is admitted by activating a redundant path in response to an operation of a row decoder or a column decoder.

FIG. 1A is a block diagram illustrating a fuse repair device included in a conventional semiconductor device.

Referring to FIG. 1A, the fuse repair device includes a fuse signal generation circuit 10 and a control signal generation circuit 20. The fuse signal generation circuit 10 stores and outputs a failed address, which indicates a location of a failed memory cell, and includes a plurality of fuse sets 10_FS_1 to 10_FS_m. The control signal generation circuit 20 outputs a control signal for a repair operation, and has a plurality of comparison units 21_CP_1 to 21_CP_m and a determination unit 22.

Hereinafter, since operations of the plurality of fuse sets 10_FS_1 to 10_FS_m are same and operations of the plurality of comparison units 21_CP_1 to 21_CP_m are same, the fuse signal generation circuit 10 and the control signal generation circuit 20 will be described with one exemplary fuse set 10_FS_1 and one exemplary comparison unit 21_CP_1.

The fuse set 10_FS_1 of the fuse signal generation circuit 10 stores a failed address of one failed memory cell with a fuse programming operation, and outputs a value RPR_BANKADDR_1<n:n+k−1> and RPR_ADDRINBANK_1<0:n−1> of the failed address corresponding to the programming of the fuse, where RPR_BANKADDR_1<n:n+k−1> is upper k bits representing a bank address in a memory, RPR_ADDRINBANK_{—1<}0:n−1> is lower n bits representing column address or row address in the bank, which is referred to as an ‘in-the-bank address’ in the specification. It is assumed in the specification that a memory cell is uniquely defined with (n+k) bits of address.

The fuse set 10_FS_1 includes an enable fuse circuit and an address fuse circuit. The enable fuse circuit has an enable fuse unit that stores whether the fuse set 10_FS_1 stores the failed address. The address fuse circuit includes the plurality of address fuse units that store the failed address.

The fuse set 10_FS_1 performs an operation for storing the failed address by programming fuses of the enable fuse circuit and the address fuse circuit and an operation for outputting a value corresponding to the programmed state of fuses of the enable fuse circuit and the address fuse circuit.

For reference, the fuse repair device included in the conventional semiconductor device may include the fuse sets 10_FS_1 to 10_FS_m of the same number as redundant memory cells for replacing failed memory cells. Moreover, the address of the memory cell may include the bank address (upper k bits of the address) and the in-the-bank address (lower n bits of the address).

For example, if the semiconductor device includes four banks and 2 to the power of 16 memory cells are included in each of the four banks, the bank address (upper bits of the address) includes four bits and the in-the-bank address of the bank includes sixteen bits. Thus, twenty address fuse units are configured.

The fuse set 10_FS_1 stores the failed address as described below. That is, a fuse of the enable fuse circuit is programmed in response to an activated rupture repair enable signal RUP_EN<1>, and the failed address is stored based on a programming operation of each fuse of the plurality of address fuse units corresponding to each bit of the subsequently inputted rupture address signals RUP_ADDRINBANK<0:n−1> and RUP_BANKADDR<n:n+k−1>.

Here, if the fuse of the enable fuse circuit is not programmed, the output signals USE_FUSE<1>, RPR_ADDRINBANK_1<0:n−1> and RPR_BANKADDR_1<n:n+k−1> of the fuse set are inactivated, and the fuse set 10_FS_1 is not used in the repair operation.

The fuse set 10_FS_1 outputs the stored failed address as described below. That is, since the fuse of the enable fuse circuit is programmed, a repair use signal USE_FUSE_1 is activated by detecting a state of the programmed fuse. And, the failed bank address RPR_BANKADDR_1<n:n+k−1> and the in-the-bank address signal RPR_ADDRINBANK_1<0:n−1> are output by detecting each fuse state of the plurality of address fuse units.

The comparison unit 21_CP_1 of the control signal generation circuit 20 compares the output RPR_ADDRINBANK_1<0:n−1> and RPR_BANKADDR_1<n:n+k−1> of the fuse set 10_FS_1 with the input address. The comparison unit 21_CP_1 activates and outputs the repair control signal RPR_EN and a normal control signal NW_DEN if the output of the fuse set is same as the input address. On the other hand, the comparison unit 21_CP_1 inactivates the repair control signal RPR_EN and the normal control signal NW_DEN if the output of the fuse set is not same as the input address ADDRINBANK<0:n−1> or BANKADDR<n:n+k−1>.

When the repair use signal USE_FUSE<1> is activated (that is, in case that the failed address is stored in the fuse set), the comparison unit 21_CP_1 compares the output RPR_ADDRINBANK_1<0:n−1> and RPR_BANKADDR_1<n:n+k−1> of the fuse set 10_FS_1 with the input address. The comparison unit 21_CP_1 activates a comparison result signal HIT_SUM<1> if the output RPR_ADDRINBANK<0:n−1> and RPR_BANKADDR<n:n+k−1> of the fuse set 10_FS_1 is same as the input address ADDRINBANK<0:n−1> and BANKADDR<n:n+k−1>. On the other hand, the comparison unit 21_CP_1 inactivates the comparison result signal HIT_SUM_1 if the output RPR_ADDRINBANK<0:n−1> and RPR_BANKADDR<n:n+k−1> of the fuse set 10_FS_1 is not same as the input address ADDRINBANK<0:n−1> or BANKADDR<n:n+k−1>. Here, when the repair use signal USE_FUSE<1> is inactivated (that is, in case that the failed address is not stored in the fuse set), the comparison unit 21_CP_1 inactivates the comparison result signal HIT_SUM<1>.

The determination unit of the control signal generation circuit 20 activates the repair control signal RPR_EN for activating the redundant path and the normal control signal NW_DEN for inactivating the normal path in response to the activated comparison result signal HIT_SUM<1:m>. If the comparison result signal HIT_SUM<1:m> is inactivated, the repair control signal RPR_EN and the normal control signal NW_DEN are inactivated, and the repair operation is not performed.

FIG. 1B is a diagram illustrating a repair process of a semiconductor device having a fuse repair device shown in FIG. 1A.

Referring to FIGS. 1A and 1B, if the semiconductor device includes two banks and performs a repair operation using redundant row decoders RD_A and RD_B for activating a redundant row path, bank address have two bits (k=2, BANKADDR<n:n+1> of values of ‘10’ and ‘01’). If one redundant row path is included in one bank, two repair control signals RPR_EN<0> and RPR_EN<1> are output from the control signal generation circuit 20. Moreover, three failed memory cells F1, F2 and F3 exist on the semiconductor device, and three failed address are stored on the first to third fuse sets 10_FS_1 to 10_FS_3, respectively.

A detailed description of the repair operation will be followed. That is, if a memory cell accessed from an external device is a second failed memory cell F2 of the failed memory cells F1, F2 and F3, when an input address ADDRINBANK<0:n−1> and BANKADDR<n:n+1> corresponding to the second failed memory cell F2, the comparison unit 21_CP_2 coupled to the second fuse set 10_FS_2 having the corresponding failed address activates a second comparison result signal HIT_SUM<2> since the failed address is same as the input address. The determination unit 22 receives the bank address BANKADDR<n:n+1>, activates a repair control signal RPR_EN<0> coupled to a first bank (BANK A) corresponding to the second failed memory cell F2, activates a normal control signal NW_DEN coupled to all banks BANK A and BANK B, and inactivates the other repair control signal RPR_EN<1>.

Thus, the normal row decoder ND_A inactivates a normal row path W_1_A of the first bank BANK_A coupled to the second failed memory cell F2 in response to the activated normal control signal NW_DEN. The redundant row decoder RD_A activates a redundant row path W_R_A of the first bank BANK_A in response to the activated repair control signal RPR_EN<0>. Subsequently, a normal column decoder CD_A activates a normal column path, and the repair operation is performed by replacing the second failed memory cell F2 by a second redundant memory cell R2. In a second bank BANK_B, a redundant row decoder RD_B inactivates a redundant row path W_R_B in response to an inactivated repair control signal RPR_EN<1>. The normal row decoder ND_B inactivates a normal row path in response to the activated normal control signal NW_DEN.

In case that one of address of the other failed memory cells F1 and F3 is input as the input address ADDRINBANK<0:n−1> and BANKADDR<n:n+1>, the normal row decoders ND_A and ND_B, which receive the activated normal control signal NW_DEN inactivate the normal row path, and the redundant row decoder RD_A of the first bank BANK_A inactivates the redundant row path W_R_A. The redundant row decoder RD_B of the second bank BANK_B that receives the activated repair control signal RPR_EN<1> activates the redundant row path W_R_B. Subsequently, the normal column decoder CD_B activates the normal column path, and the repair operation is performed by replacing the failed memory cells F1 and F3 by the redundant memory cells R1 and R3.

As described above, if the fuse repair device included in the conventional semiconductor device includes three failed memory cells, since the other fuse sets different from three fuse sets for storing the failed address of the three failed memory cells are not used for the repair operation, the other fuse sets occupies unnecessary chip areas.

Moreover, since the fuse set for storing multipurpose information in the conventional semiconductor device is not used for the repair operation, a specific fuse unit for storing the multipurpose information must be configured. Although the fuse set that is not used for storing the failed address exist, since the specific fuse unit for storing the multipurpose information is further configured, the inefficient use of the chip area may become a concern.

### SUMMARY

Exemplary embodiments of the present invention are directed to a fuse repair device and a repair method using the same for storing a failed address and multipurpose information on one fuse set.

In accordance with an embodiment of the present invention, a fuse repair device may include a first fuse circuit configured to store a first portion out of a failed address, a second fuse circuit configured to store a multipurpose information or a second portion of the failed address, an enable control circuit configured to provide a first enable signal to enable the second fuse unit based on a first control signal, a switch control circuit configured to provide a second enable signal to enable the second fuse unit based on a second control signal, a repair control signal generation circuit configured to compare data stored in the first fuse circuit and selectively further in the second fuse circuit with an input address, and generate a repair control signal based on the first enable signal and the second enable signal and a multipurpose control signal generation circuit configured to generate a multipurpose control signal to control operations different from a repair operation based on data stored in the second fuse circuit and the second control signal.

In accordance with another embodiment of the present invention, a fuse repair device may include a fuse circuit configured to store a failed address or a multipurpose information, an enable control circuit configured to control a repair operation in response to the failed address stored on the fuse unit, a switch control circuit configured to store whether the multipurpose information is programmed on the fuse unit, a repair control signal generation circuit configured to compare the failed address stored on the fuse circuit with an input address based on an output of the enable control circuit and an output of the switch control circuit, and generate a repair control signal for activating a redundant path for the failed memory cell based on a comparison result, and a multipurpose control signal generation circuit configured to generate a multipurpose control signal to control other operations different from the repair operation with the multipurpose information stored on the fuse circuit based on the output of the switch control circuit.

In accordance with another embodiment of the present invention, a fuse repair method may include storing a part of a failed address on a fuse circuit to store the failed address, receiving an input address, comparing the part of the failed address with a corresponding part of the input address, and activating a redundant path for a normal memory cell that is not identified with the part of the failed address based on a comparison result, and exchanging the normal memory cell to the redundant cell by activating the redundant path.

### BRIEF DESCRIPTION OF THE DRAWINGS

FIG. 1A is a block diagram illustrating a fuse repair device included in a conventional semiconductor device.

FIG. 1B is a diagram illustrating a repair process of a semiconductor device having a fuse repair device shown in FIG. 1A.

FIG. 2 is a block diagram illustrating a fuse repair device in accordance with an embodiment of the present invention.

FIG. 3A is a detailed circuit diagram illustrating an enable fuse unit of an enable control circuit and a switch fuse unit of a switch control circuit shown in FIG. 2 in accordance with an embodiment of the present invention.

FIG. 3B is a detailed circuit diagram illustrating an address fuse unit of a first fuse circuit shown in FIG. 2 in accordance with an embodiment of the present invention.

FIG. 3C is a detailed circuit diagram illustrating an address fuse unit of a second fuse circuit shown in FIG. 2 in accordance with an embodiment of the present invention.

FIG. 4A is a detailed circuit diagram illustrating a first comparison unit of a repair control signal generation circuit shown in FIG. 2 in accordance with an embodiment of the present invention.

FIG. 4B is a detailed circuit diagram illustrating a second comparison unit of a repair control signal generation circuit shown in FIG. 2 in accordance with an embodiment of the present invention.

FIG. 5 is a diagram illustrating a repair process using a redundant row decoder in a semiconductor device having a fuse repair device shown in FIG. 2 in accordance with an embodiment of the present invention.

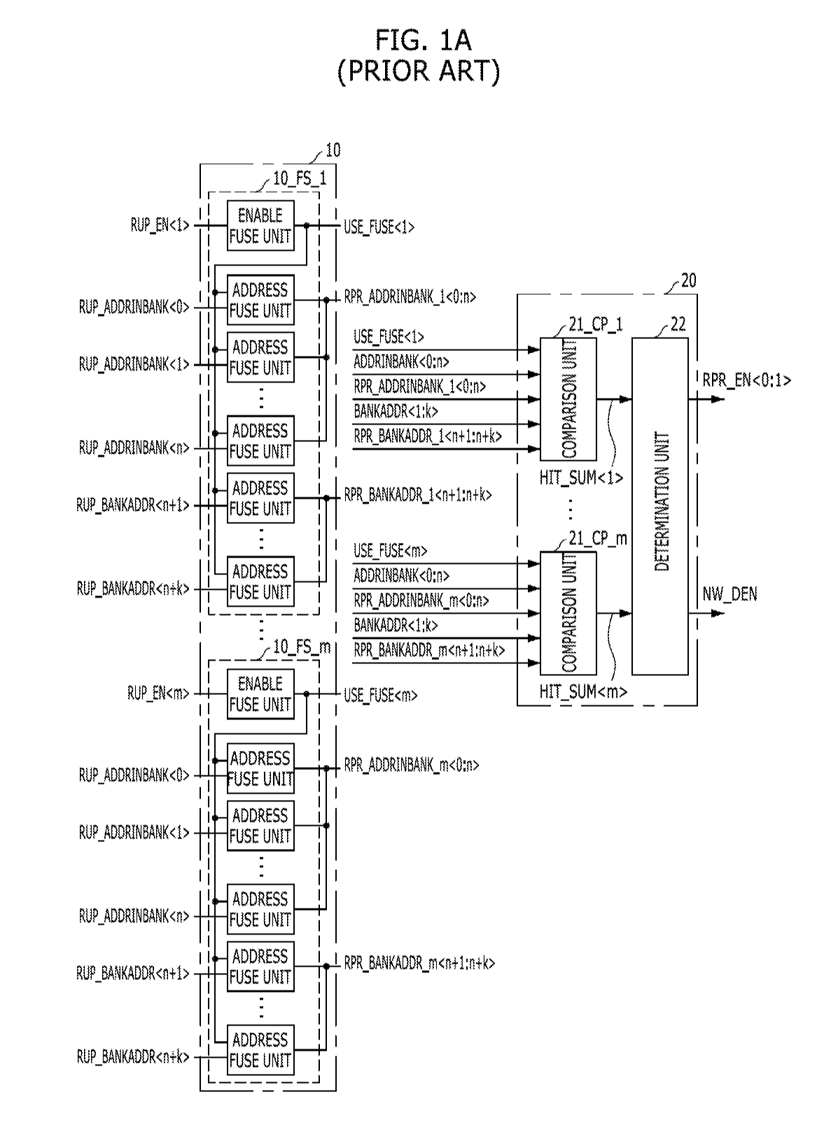

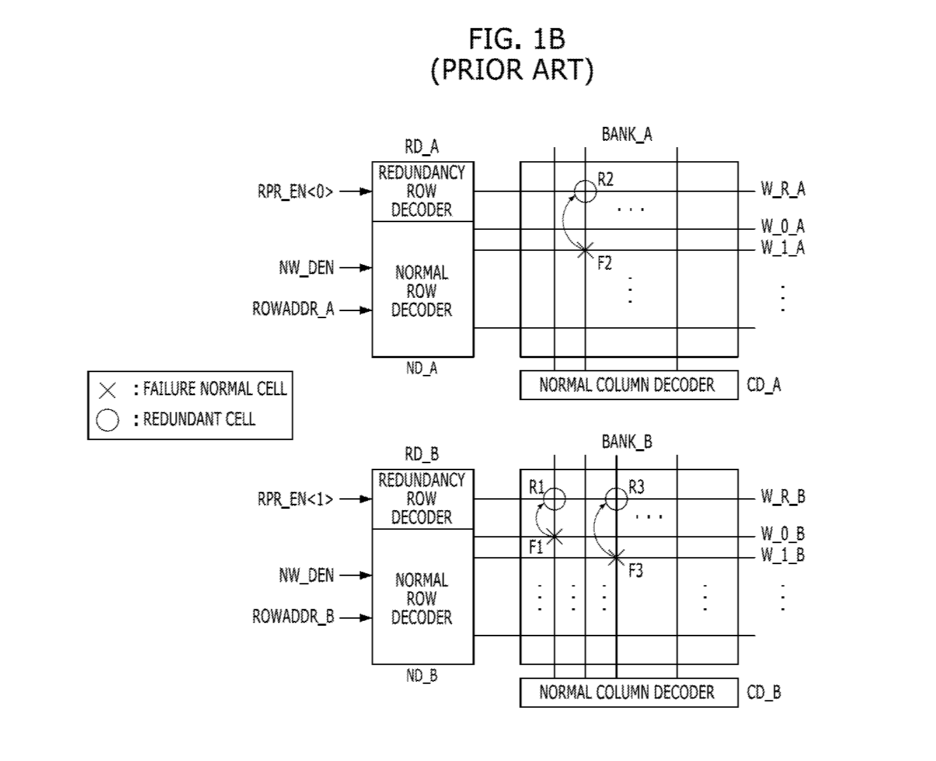

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, reference numerals correspond directly to the like parts in the various figures and embodiments of the present invention. It is also noted that in this specification, “connected/coupled” refers to one component not only directly coupling another component but also indirectly coupling another component through an intermediate component. In addition, a singular form may include a plural form as long as it is not specifically mentioned in a sentence.

Hereinafter, for a clear description, it is assumed that a semiconductor device having a fuse repair device in accordance with exemplary embodiments of the present invention includes four banks, each of four banks has sixteen word lines and eight column lines and a redundant row decoder having one redundant path. Thus, the bank address is four bits, the in-the-bank address 7 bits (four bits for word addresses, and three bits for column addresses), and eight redundant cells.

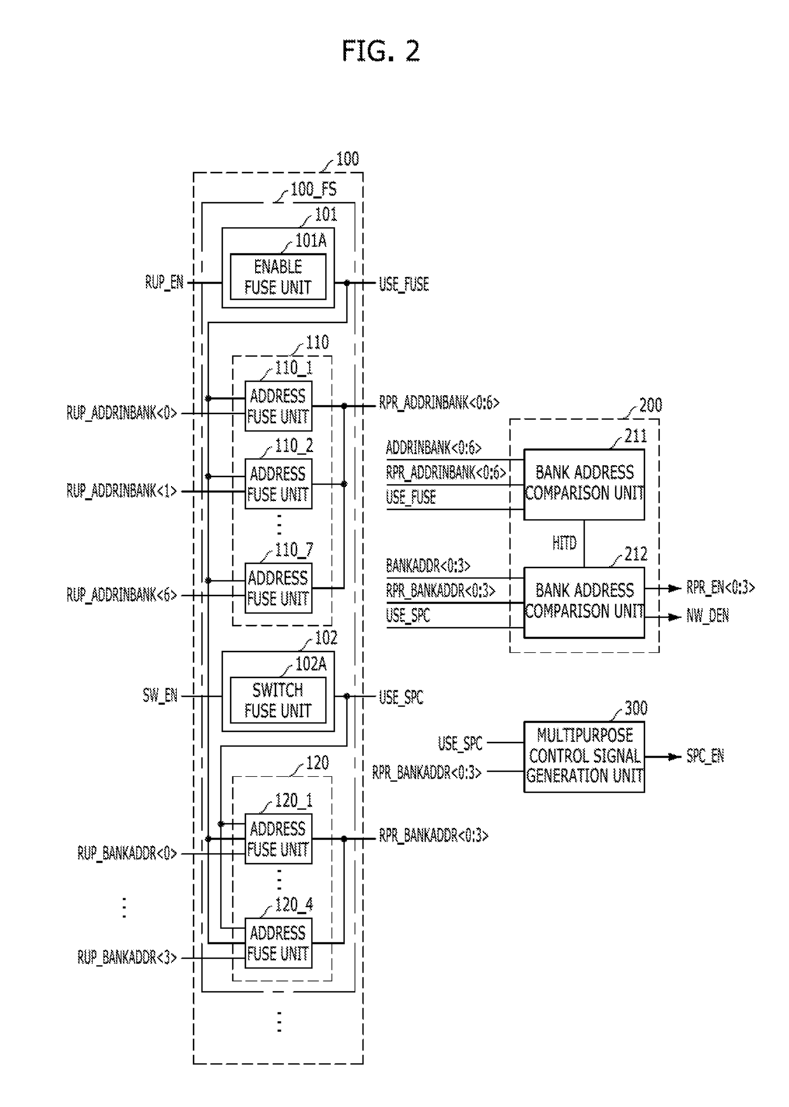

FIG. 2 is a block diagram illustrating a fuse repair device in accordance with an embodiment of the present invention.

Referring to FIG. 2, a fuse repair device in accordance with an embodiment of the present invention includes a plurality of fuse sets 100, a repair control signal generation circuit 200 and a multipurpose control signal generation circuit 300.

Here, since the plurality of fuse sets 100 perform same operations, for the clear and concise descriptions, one fuse set 100_FS will be described as below.

The fuse set 100_FS includes an enable control circuit 101, a switch control circuit 102, a first fuse circuit 110 and a second fuse circuit 120.

The enable control circuit 101 includes one enable fuse unit 101A for generating a repair use signal USE_FUSE that controls a repair operation. A fuse included in the enable fuse unit 101A of the enable control circuit 101 is ruptured in response to an activated rupture enable signal RUP_EN and outputs the repair use signal USE_FUSE having a different logic value based on the rupture state of the fuse.

The switch control circuit 102 stores whether the multipurpose information is programmed on the second fuse circuit 120 and generates multipurpose use signal USE_SPC for controlling the multipurpose control signal generation circuit 300. The switch control circuit 102 includes one switch control circuit 102A. A fuse included in the switch control circuit 102A is ruptured in response to an activated switch enable signal SW_EN and outputs the multipurpose use signal USE_SPC having a different logic value based on the rupture state of the fuse.

The first fuse circuit 110 includes a plurality of address fuse units 110_1 to 110_7 and stores an in-the-bank address of seven bits, which is a lower part of the failed address.

The second fuse circuit 120 includes a plurality of address fuse units 120_1 to 120_4 and stores the multipurpose information of four bits or a bank address of four bits, which is an upper part of the failed address.

More specifically, the fuse set 100_FS stores, the 11 bits of the failed address, the 4 bits the multipurpose information, or both of the 4 bits of the multipurpose information and the lower 7 bits of the failed address. These three kinds of information storage types in the fuse set (100_FS) are classified based on the output signals USE_FUSE and USE_SPC of the enable control circuit 101 and the switch control circuit 102 as shown in TABLE 1. In TABLE 1, notation “NR” indicates ‘not ruptured’, notation “R” indicates ‘ruptured’, “0” indicates ‘disabled’, “1” indicates ‘enabled’.

TABLE 1
Information

| Stored | Enable control circuit (101) | | | Switch control circuit (102) | | |
|---|---|---|---|---|---|---|
| In the fuse set | Rupture enable | | Repair use | Switch | | Multipurpose |
| (100_FS) | (RUP_EN) | Fuse | (USE_FUSE) | enable | Fuse | use (USE_SPC) |
| Failed address | 1 | R | 1 | 0 | NR | 0 |
| (whole 11 bits) | | | | | | |
| Multipurpose | 0 | NR | 0 | 1 | R | 1 |
| information | | | | | | |
| (4 bits) | | | | | | |
| Failed address | 1 | R | 1 | 1 | R | 1 |
| (lower 7 bits) | | | | | | |
| and multipurpose | | | | | | |
| information (4 bits) | | | | | | |

In case that the fuse set 100_FS stores all bits of the failed address as shown in TABLE 1, the fuse set 100_FS receives an activated rupture enable signal RUP_EN, and the failed address is programmed and stored on the fuse set 100_FS by rupturing the fuse of the enable control circuit 101. The fuse set 100_FS receives an in-the-bank address (that is, lower 7 bits of the input address) as a rupture in-the-bank address signal RUP_ADDRINBANK<0:6> and stores the in-the-bank address based on the rupture operation of the address fuse units 110_1 to 110_7 of the first fuse circuit 110 corresponding to each bit. The fuse set 100_FS receives a bank address (that is, upper 4 bits of the input address) as a rupture bank address signal RUP_BANKADDR<0:3> and stores the bank address based on the rupture operation of the address fuse units 120_1 to 120_4 of the second fuse circuit 120.

Herein, if the fuse of the enable control circuit is ruptured, the activated repair use signal USE_FUSE is output. If the fuse of the switch control circuit 102 is not ruptured, and the multipurpose use signal USE_SPC is inactivated, the repair control signal generation circuit 200 is activated and receives the failed address stored on the fuse set 100_FS, and the multipurpose control signal generation circuit 300 is inactivated and does not operate.

In case that the fuse set 100_FS stores only multipurpose information as shown in TABLE 1, the fuse set 100_FS receives an activated switch enable signal SW_EN, and the multipurpose information is programmed and stored on the second fuse circuit of the fuse set 100_FS by rupturing the fuse of the switch control circuit 102. The fuse set 100_FS receives the multipurpose information with the rupture bank address signal RUP_BANKADDR<0:3>, and the multipurpose information is stored based on the rupture operation of the address fuse units 120_1 to 120_4 of the second fuse circuit 120.

Herein, if the fuse of the enable control circuit 101 is not ruptured, the activated repair use signal USE_FUSE is inactivated. If the fuse of the switch control circuit 102 is ruptured, and the multipurpose use signal USE_SPC is activated, the repair control signal generation circuit 200 is inactivated and does not operate, and the multipurpose control signal generation circuit 300 is activated and receives the multipurpose information stored on the second fuse circuit 120.

In case that the fuse set 100_FS stores an in-the-bank address (that is, lower 7 bits of the input address) and multipurpose information as shown in TABLE 1, the fuse set 100_FS receives an activated switch enable signal SW_EN, and the multipurpose information is programmed and stored on the second fuse circuit of the fuse set 100_FS by rupturing the fuse of the switch control circuit 102. The fuse set 100_FS receives the multipurpose information with the rupture bank address signal RUP_BANKADDR<0:3>, and the multipurpose information is stored based on the rupture operation of the address fuse units 120_1 to 120_4 of the second fuse circuit 120. In order to store the in-the-bank address, the bank address is programmed and stored on the first fuse circuit 110 by receiving an activated rupture enable signal RUP_EN and by rupturing the fuse of the enable control circuit 101. The bank address is received as the in-the-bank rupture bank address signal RUP_ADDRINBANK<0:6> and stored based on the rupture operation of the address fuse units 110_1 to 110_7 of the first fuse circuit 110.

Herein, in case that the fuse of the enable control circuit 101 is ruptured and activates the repair use signal USE_FUSE and the fuse of the switch control circuit 102, the repair control signal generation circuit 200 is activated and receives the information stored on the first fuse circuit 110, and the multipurpose control signal generation circuit 300 is activated and receives the multipurpose information stored on the second fuse circuit 120.

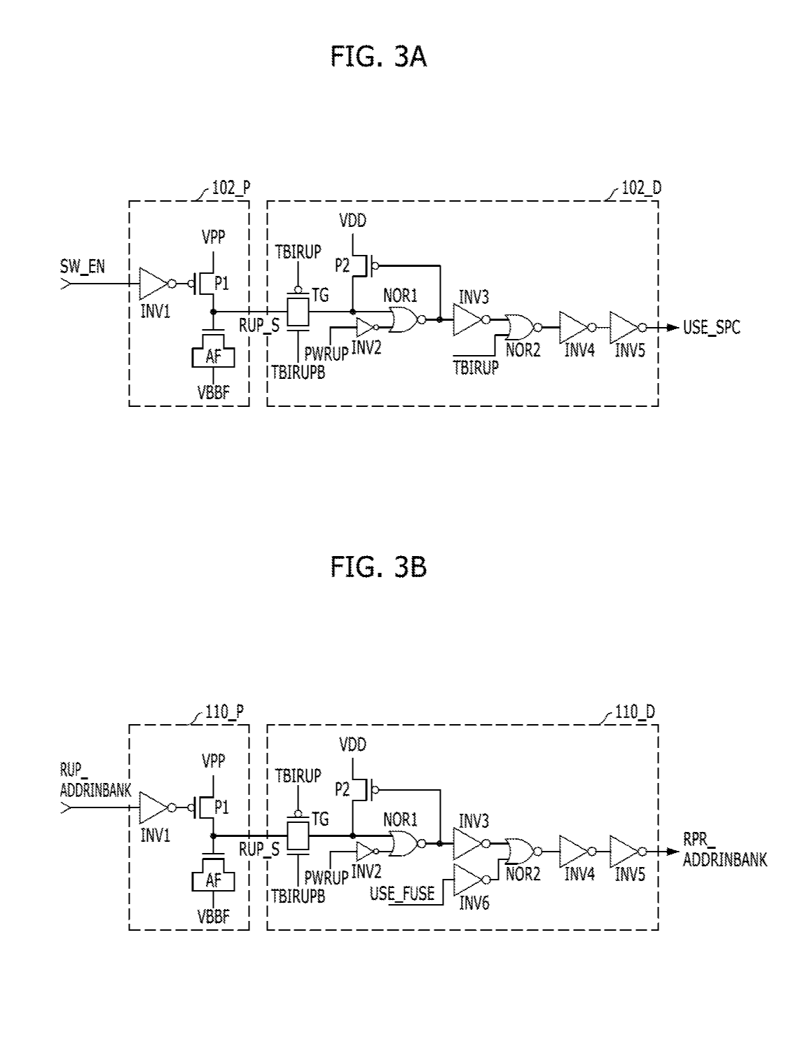

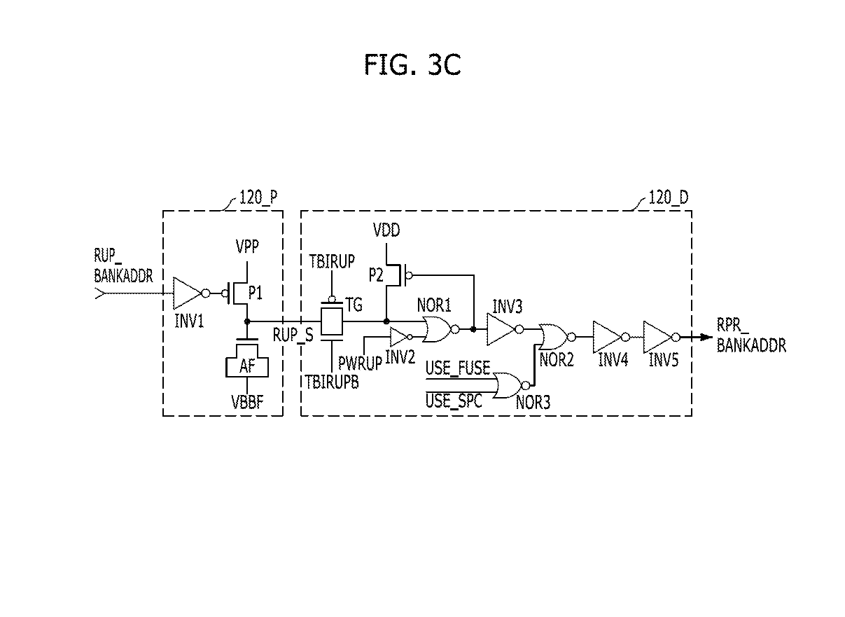

FIG. 3A is a detailed circuit diagram of the enable fuse unit of the enable control circuit and the switch fuse unit of the switch control circuit in FIG. 2 in accordance with an embodiment of the present invention. FIG. 3B is a detailed circuit diagram of the address fuse unit of the first fuse circuit shown in FIG. 2 in accordance with an embodiment of the present invention. FIG. 3C is a detailed circuit diagram of the address fuse unit of the second fuse circuit shown in FIG. 2 in accordance with an embodiment of the present invention.

Referring to FIG. 3A, the enable fuse unit 101A of the enable control circuit 101 includes a program unit 101_P and a detection unit 101_D. The switch fuse unit 102A of the switch control circuit 102 includes a program unit 102_P and a detection unit 102_D. Since the switch fuse unit 102A has same configuration and operation as the enable fuse unit 101A of the enable control circuit 101, the detailed description of the switch fuse unit 102A will be omitted for the convenience of description.

The program unit 101_P includes a first inverter INV1, a first PMOS transistor P1 and a fuse AF. The first inverter INV1 receives and inverts the rupture enable signal RUP_EN. The first PMOS transistor P1 amplifies an inverted rupture enable signal. A source of the first PMOS transistor P1 is coupled to a program voltage VPP, and a gate of the first PMOS transistor P1 is coupled to the first inverter INV1. The PMOS transistor P1 supplies a program voltage VPP to the fuse AF in response to the inverted rupture enable signal having a logic HIGH. The fuse AF performs a rupture operation for changing an open state to a short state by supplying a voltage to the both ends and rupturing the fuse. An end of the fuse AF is coupled to a drain of the first PMOS transistor. The other end of the fuse is coupled to a program base voltage VBBF. When the inverted rupture enable signal is inactivated at the logic LOW, the rupture does not occur. A rupture state signal RUP_S having a different logic level based on the rupture state of the fuse AF is output.

The detection unit 101_D receives a power up signal PWRUP and detection start signals TBIRUP and TBIRUPb that have an inverted phase each other. The detection unit 101_D activates and outputs the repair use signal USE_FUSE at a logic HIGH when the fuse AF is ruptured, and inactivates and outputs the repair use signal USE_FUSE at a logic LOW when the fuse AF is not ruptured.

A transmission gate TG receives the rupture state signal RUP_S in response to the detection start signals TBIRUP and TBIRUPB, and an output of the transmission gate TG is input to an input node of a first NOR gate NOR1. A second inverter INV2 receives the power up signal PWRUP and outputs an inverted power up signal. The first NOR gate NOR1 receives the inverted power up signal from the second inverter INV2 through another input node. An output of the first NOR gate NOR1 is input to an input node of a second NOR gate NOR2 via a third inverter INV3. The second NOR gate NOR2 receives the detection start signal SBIRUP through another input node, an output of the second NOR gate NOR2 is input to a fourth inverter INV4, which is coupled to a fifth inverter INV5. The fifth inverter INV5 outputs the repair use signal USE_FUSE.

Moreover, a second PMOS transistor P2 receives an output of the first NOR gate NOR1 through a gate of the second PMOS transistor P2. A source of the second PMOS transistor P2 is coupled to a power supply voltage (VDD). A drain of the second PMOS transistor P2 is coupled to an output of the transmission gate TG. When the transmission gate TG has an output of a logic HIGH, the second PMOS transistor P2 prevents a voltage from being lowered.

Herein, if the detection start signal TBIRUP having a logic LOW and the power up signal PWRUP having a logic HIGH are input, both ends of the transmission gate TG are passed. The rupture state signal RUP_S which represents the rupture state of the fuse AF is output as the repair use signal via the first NOR gate NOR1, the third inverter INV3, the second NOR gate NOR2, the fourth inverter INV4 and the fifth inverter INV5. If the fuse AF is ruptured, the repair use signal USE_FUSE is activated at a logic HIGH. If the fuse AF is not ruptured, the repair use signal USE_FUSE is inactivated at a logic LOW.

Referring to FIG. 3B, each of the address fuse units 110_1 to 110_7 of the first fuse circuit 110 includes a program unit 110_P and a detection unit 110_D. Since each of the address fuse units 110_1 to 110_7 of the first fuse circuit 110 has same configuration and operation as the enable fuse unit 101A of the enable control circuit 101, the detailed description of the address fuse units 110_1 to 110_7 will be omitted.

Herein, in case that the rupture state of the fuse AF of the program unit 110_P is detected, when the repair use signal USE_FUSE is activated at a logic HIGH (that is, the enable control circuit 101 of the fuse set 100_FS performs a rupture operation), the rupture state is detected by the failed in-the-bank address RPR_ADDRINBANK, and when the repair use signal USE_FUSE is inactivated at a low logic value, the failed in-the-bank address RPR_ADDRINBANK is inactivated at a logic LOW irrespective of the rupture state of the fuse AF.

Referring to FIG. 3C, the address fuse units 120_1 to 120_4 of the second fuse circuit 120 includes a program unit 120_P and a detection unit 120_D. Each of the address fuse units 120_1 to 120_4 of the second fuse circuit 120 has same configuration and operation as the enable fuse unit 101A of the enable control circuit 101 except a third NOR gate NOR3.

The third NOR gate NOR3 receives the repair use signal USE_FUSE and multipurpose use signal USE_SPC. An output of the third NOR gate NOR3 is input to an input node of the second NOR gate NOR2. Herein, in case that the rupture state of the fuse AF of the program unit 120_P is detected, if one of the repair use signal USE_FUSE and the multipurpose repair signal USE_SPC is activated at a logic HIGH, the rupture state of the fuse AF is detected by the bank address signal RPR_ADDRINBANK. If all of the repair use signal USE_FUSE and the multipurpose repair signal USE_SPC are inactivated at a logic LOW, the bank address signal RPR_ADDRINBANK is inactivated at a logic LOW irrespective of the rupture state of the fuse AF.

Referring back to FIG. 2, the repair control signal generation circuit 200 includes a first comparison unit 211 and a second comparison unit 212.

In case that the first comparison unit 211 receives an activated repair use signal USE_FUSE, the first comparison unit 211 compares the failed in-the-bank address RPR_ADDRINBANK<0:6> with an in-the-bank address signal ADDRINBANK<0:6> of the input address. If the failed in-the-bank address RPR_ADDRINBANK<0:6> is same as the in-the-bank address signal ADDRINBANK<0:6>, a comparison result signal HITD is activated, and if the failed in-the-bank address RPR_ADDRINBANK<0:6> is not same as the in-the-bank address signal ADDRINBANK<0:6>, the comparison result signal HITD is inactivated. Herein, if the repair use signal USE_FUSE is inactivated, the comparison result signal HITD is inactivated.

In case that the second comparison unit 212 receives an activated comparison result signal HITD and an inactivated multipurpose use signal USE_SPC, the second comparison unit 212 compares the failed bank address RUP_BANKADDR<0:3> with a bank address signal BANKADDR<0:3> of the input address. If the failed bank address RUP_BANKADDR<0:3> is same as the bank address signal BANKADDR<0:3>, one of the repair control signal RPR_EN<0:3> is activated, and the normal control signal NW_DEN is activated. Herein, if second comparison unit 212 receives the inactivated comparison result signal HITD, the repair control signal PRP_EN<0:3> is inactivated and the normal control signal NW_DEN is inactivated.

On the contrary, in case that the second comparison unit 212 receives an activated comparison result signal HITD and an activated multipurpose use signal USE_SPC, the second comparison unit 212 activates and outputs the repair control signal RPR_EN<0:3> and the control signal NW_DEN irrespective of the comparison result between the failed bank address RUP_BANKADDR<0:3> and the bank address signal BANKADDR<0:3>.

If the repair control signal RPR_EN<0:3> is activated and the normal control signal NW_DEN is activated, the activated repair control signal RPR_EN<0:3> activates a redundant row path that is an access to a redundant memory cell, and the activated normal control signal NW_DEN inactivates a normal row path that is an access to a normal memory cell. On the contrary, if the repair control signal RPR_EN<0:3> is inactivated and the normal control signal NW_DEN is inactivated, the inactivated repair control signal RPR_EN<0:3> inactivates the redundant row path that is an access to the redundant memory cell, and the inactivated normal control signal NW_DEN activates the normal row path that is an access to the normal memory cell.

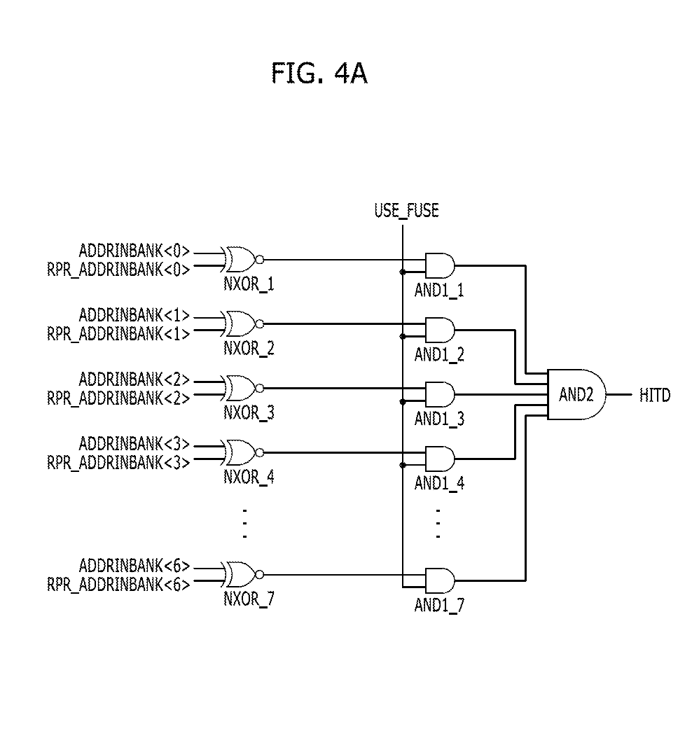

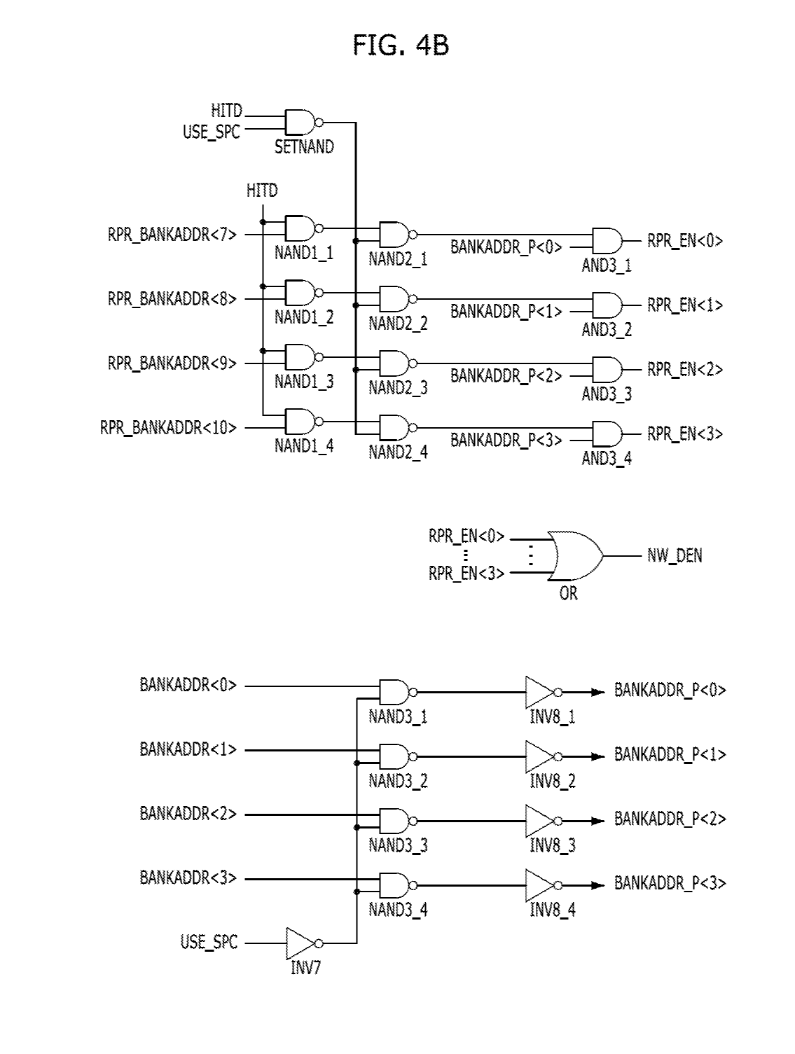

FIG. 4A is a detailed circuit diagram illustrating the first comparison unit of the repair control signal generation circuit shown in FIG. 2 in accordance with an embodiment of the present invention. FIG. 4B is a detailed circuit diagram illustrating the second comparison unit of the repair control signal generation circuit shown in FIG. 2 in accordance with an embodiment of the present invention.

Referring to FIG. 4A, the first comparison unit 211 includes a plurality of XNOR gates XNOR_1 to XNOR_7, a plurality of first AND gates AND1_1 to AND1_7 and a second NAND gate NAND2.

Each of the plurality of XNOR gates XNOR_1 to XNOR_7 receives the failed in-the-bank address RPR_ADDRINBANK<0:6> and the in-the-bank address signal ADDRINBANK<0:6> of input address, performs an XNOR logic operation, and outputs the XNOR logic operation result to one node of each of the plurality of first AND gates AND1_1 to AND1_7.

Each of the plurality of first AND gates AND1_1 to AND1_7 receives the XNOR logic operation result from the each of the plurality of XNOR gates XNOR_1 to XNOR_7 and the repair use signal USE_FUSE, and outputs an AND logic operation result to the second AND gate AND2.

The second AND gate NAND2 performs an AND logic operation with the output of the plurality of AND gates AND1_0 to AND1_6 and outputs the comparison result signal HITD as the AND logic operation result.

In case that the first comparison unit 211 receives the repair use signal USE_FUSE that is activated at the logic HIGH, if the failed in-the-bank address RPR_ADDRINBANK<0:6> is same as the corresponding low bit part ADDRINBANK<0:6> of input address, the first comparison unit 211 outputs the comparison result signal HITD that is activated at the logic HIGH. If the failed in-the-bank address RPR_ADDRINBANK<0:6> is not same as the corresponding low bit part ADDRINBANK<0:6> of input address, the first comparison unit 211 outputs the comparison result signal HITD that is inactivated at the logic LOW. In contrary to, in case that the first comparison unit 211 receives the repair use signal USE_FUSE which is inactivated at the logic LOW, the first comparison unit 211 outputs the comparison result signal HITD that is inactivated at the logic LOW irrespective of the comparison result.

Referring to FIG. 4B, the second comparison unit 212 includes a plurality of first NAND gates NAND1_1 to NAND1_4, a SETNAND gate SETNAND, a plurality of second NAND gates NAND2_1 to NAND2_4, a plurality of third AND gates AND3_1 to AND3_4, a seventh inverter INV7, a plurality of third NAND gates NAND3_1 to NAND3_4, a plurality of eighth inverters INV8_1 to INV8_4, and an OR gate OR.

Each of the plurality of first NAND gates NAND1_1 to NAND1_4 receives the comparison result signal HITD and the failed bank address RPR_BANKADDR<0:3>. The output of each of the plurality of first NAND gates NAND1_1 to NAND1_4 is input to each of the plurality of second NAND gates NAND2_1 to NAND2_4.

The SETNAND gate SETNAND receives the comparison result signal HITD and the multipurpose use signal USE_SPC, and outputs a NAND operation result to each of the plurality of second NAND gate NAND2_1 to NAND2_4. The second NAND gates NAND2_1 to NAND2_4 perform a NAND operation with the output signal of the SETNAND gate and the output of each of the plurality of first NAND gates NAND1_1 to NAND1_4, and outputs the NAND operation result to the plurality of third AND gates AND3_1 to AND3_4.

Each of the plurality of third AND gates AND3_1 to AND3_4 performs an AND operation with the output of each of the plurality of second NAND gates NAND2_1 to NAND2_4 and a conversion bank address BANKADDR_P<0:3>, which is received from each of the plurality of eighth inverters INV8_1 to INV8_4. Each of the plurality of third AND gates AND3_1 to AND3_4 outputs the repair control signal RPR_EN<0:3> as the AND operation result to the OR gate OR.

The seventh inverter INV7 receives and inverts the multipurpose use signal USE_SPC and outputs an inverted multipurpose use signal to each of the plurality of third NAND gates NAND3_1 to NAND3_4. The third NAND gates NAND3_1 to NAND3_4 perform a NAND operation with an input bank address BANKADDR<0:3> and the inverted multipurpose use signal received from each of the plurality of third NAND gates NAND3_1 to NAND3_4, and outputs the NAND operation result to each of the plurality of eighth inverters INV8_1 to INV8_4. Each of the plurality of eighth inverters INV8_1 to INV8_4 inverts the output of each of the third NAND gates NAND3_1 to NAND3_4 and outputs the conversion input bank address BANKADDR_P<0:3> as the inverting operation result to each of the plurality of third AND gates AND3_1 to AND3_4.

The OR gate OR receives the repair control signal RPR_EN<0:3> from each of the plurality of third AND gates AND3_1 to AND3_4, performs an OR operation with the repair control signal RPR_EN<0:3>, and outputs the normal control signal NW_DEN as the OR operation result.

Referring back to FIG. 2, if the multipurpose control signal generation circuit 300 receives the activated multipurpose use signal USE_SPC and the failed bank address RPR_BANKADDR<0:3>, the multipurpose control signal generation circuit 300 activates and outputs the multipurpose control signal SPC_EN.

Hereinafter, the operation of the fuse repair device in accordance with the embodiment of the present invention will be described in details as below.

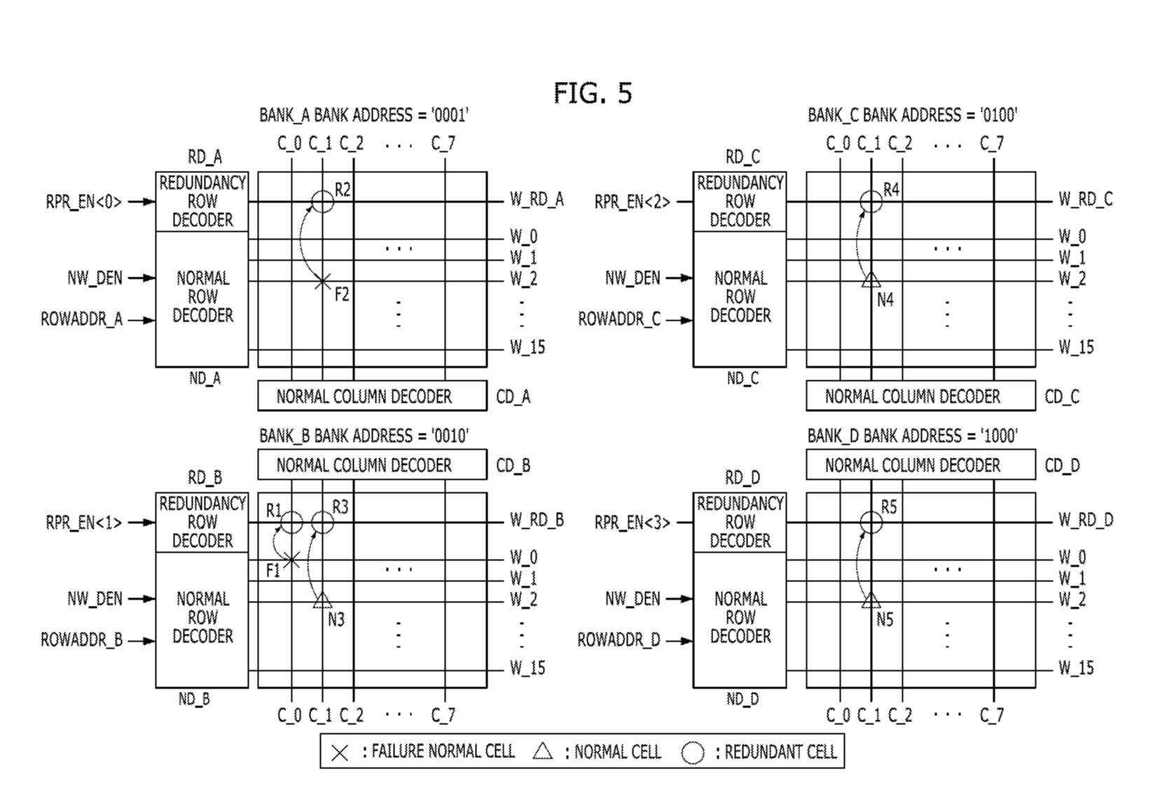

FIG. 5 is a diagram illustrating a repair process using a redundant row decoder in a semiconductor device having the fuse repair device shown in FIG. 2 in accordance with an embodiment of the present invention.

Referring to FIG. 5, since it is assumed that a semiconductor device including the repair device in accordance with an embodiment of the present invention includes four banks, and each of four banks has only a redundant row decoder having only one redundant row path, the semiconductor device including the repair device includes normal row decoders ND_A, ND_B, ND_C and ND_D, a redundant row decoder RD_A, RD_B, RD_C and RD_D and a normal column decoder CD_A, CD_B, CD_C and CD_D of each bank.

Referring to FIGS. 2 and 5, in the semiconductor device including the repair device in accordance with the embodiment of the present invention, in case that the failed address for indicating a location of a first failed memory cell F1 is stored on the fuse set 100_FS, when the memory cell that is indicated by the input address ADDRINBANK<0:6> and BANKADDR<0:3> is a failed memory cell F1, the repair operation will be described as below.

The address fuse units 110_1 to 110_7 of a first fuse circuit 110 store the failed in-the-bank address signal RPR_ADDRINBANK<0:6> of seven bits for the failed memory cell F1 based on the rupture operation. The address fuse units 120_1 to 120_4 of the second fuse circuit 120 store the failed bank address signal RPR_BANKADDR<0:3> of four bits for the failed memory cell F1 based on the rupture operation. The repair use signal USE_FUSE is activated at the logic HIGH. The multipurpose control signal generation circuit 300 for receiving the multipurpose use signal USE_SPC, which is inactivated at the logic LOW, is inactivated and does not operate.

Thus, if the input address ADDRINBANK<0:6> and BANKADDR<0:3> is same as the address of the failed memory cell, the first comparison unit 211 of the repair control signal generation circuit 200 that receives the repair use signal USE_FUSE activated at the logic HIGH activates the comparison result signal HITD at the logic HIGH, and the second comparison unit 212 of the repair control signal generation circuit 200 that receives the repair use signal USE_FUSE inactivated at the logic LOW compares the failed bank address RPR_BANKADDR<0:3> with the bank address BANKADDR<0:3>. If the failed bank address RPR_BANKADDR<0:3> is same as the bank address BANKADDR<0:3>, the second comparison unit 212 activates the repair control signal RPR_EN<1> for the second bank BANK_B and inactivates the normal control signal NW_DEN.

Thus, a redundant row decoder RD_B of the second bank BANK_B, which receives the repair control signal RPR_EN<1> activated at the logic HIGH, activates a redundant row path W_RD_B. A normal row decoder ND_B of the second bank BANK_B, which receives the normal control signal NW_DEN activated at the logic HIGH, inactivates a normal row path W_0 for the failed memory cell F1. And then, a normal column decoder CD_B of the second bank BANK_B activates a normal column path C_0 corresponding to a column address out of the input address ADDRINBANK<0:6> and BANKADDR<0:3>, and performs a repair operation by replacing the failed memory cell F1 by a redundant cell R1. For reference, the normal column decoder CD_B may be operated prior to the redundant row decoder RD_B.

In case that an in-the-bank address of the failed address for indicating the location of the first failed memory cell F2 is stored on the first fuse circuit 110 of the fuse set 100_FS, when the memory cell which is indicated by the input address ADDRINBANK<0:6> and BANKADDR<0:3> as the failed memory cell F2, the repair operation will be described as below.

The address fuse units 110_1 to 110_7 of the first fuse circuit 110 store the failed in-the-bank address signal RPR_ADDRINBANK<0:6> of seven bits for the failed memory cell F2 based on the rupture operation, and outputs the failed in-the-bank address RPR_ADDRINBANK<0:6>. The address fuse units 120_1 to 120_4 of the second fuse circuit 120 store the multipurpose information and outputs the failed bank address RPR_BANKADDR<0:3> as the multipurpose information based on the rupture operation. The repair use signal USE_FUSE is activated at the logic HIGH and the multipurpose use signal USE_SPC is activated at the logic HIGH. The multipurpose control signal generation circuit 300 receives the multipurpose use signal USE_SPC activated at the logic HIGH and the failed bank address RPR_BANKADDR<0:3> as the multipurpose information, and activates the multipurpose control signal SPC_EN for controlling other operations different from the repair operation.

Thus, if the input address ADDRINBANK<0:6> and BANKADDR<0:3> that is same as the address of the failed memory cell F2 is received, the first comparison unit 211 of the repair control signal generation circuit 200 that receives the repair use signal USE_FUSE activated at the logic HIGH activates the comparison result signal HITD at the logic HIGH. The second comparison unit 212, which receives the multipurpose use signal USE_SPC activated at the logic HIGH, activates the repair control signal RPR_EN<0:3> for all banks at the logic high level and activates the normal control signal NW_DEN at the logic HIGH irrespective of the comparison result of the failed bank address RPR_BANKADDR<0:3> and the bank address BANKADDR<0:3>.

Thus, the redundant row decoder RD_A of the first bank BANK_A, which receives the repair control signal RPR_EN<0> activated at the logic HIGH, activates the redundant row decoder W_RD_A. The normal row decoder ND_A of the first bank BANK_A, which receives the normal control signal NW_DEN activated at the logic HIGH, inactivates a normal row path W_2. And then, the normal column decoder CD_A of the first bank BANK_A activates a normal column path C_1 corresponding to a column address out of the input address ADDRINBANK<0:6> and BANK_ADDR<0:3>, and performs a repair operation for replacing the failed memory cell F2 with a redundant memory cell R2. For reference, the normal column decoder CD_A may be performed prior to the redundant row decoder RD_A.

Moreover, in case that the address normal memory cells N3, N4 or N5 instead of the failed memory cell F2 is received as the input address ADDRINBANK<0:6> and BANKADDR<0:3>, if the in-the-bank address of the normal memory cells N3, N4 or N5 is same as the in-the-bank address of the failed memory cell F2, the repair operation is performed. In case that the address of the normal memory cell N3 having the same in-the-bank address as the in-the-bank address of the failed memory cell F2 is input as the input address ADDINBANK<0:6> and BANKADDR<0:3>, the first comparison unit 211 of the repair signal generation circuit 200 that receives the repair use signal USE_FUSE activated at the logic HIGH activates the comparison result signal HITD at the logic HIGH. The second comparison unit 212 of the repair signal generation circuit 200 that receives the multipurpose use signal USE_SPC activated at the logic HIGH activates the repair control signal RPR_EN<0:3> for all banks and activates the normal control signal NW_DEN at the logic HIGH irrespective of the comparison result of the failed bank address RPR_BANKADDR<0:3> and the bank address BANKADDR<0:3>.

Thus, the redundant row decoder RD_B of the second bank BANK_B that receives the repair control signal RPR_EN<0> activated at the logic HIGH activates the redundant row path W_RD_B. The normal row decoder ND_B of the second bank BANK_B that receives the normal control signal NW_DEN activated at the logic HIGH inactivates the normal row path W_2. And then, the normal column decoder of the second bank BANK_B activates the normal column path C_1 corresponding to the column address of the input address ADDRINBAK<0:6> and BANKADDR<0:3>, and performs the repair operation for replacing the normal memory cell F3 with the redundant memory cell R3. For reference, the normal column decoder CD_B may be performed prior to the row decoder RD_B.

According to the embodiment of the present invention, the configuration and the operation of the normal memory cells N4 and N5 are substantially the same as described above in connection with the normal memory cell N3.

In conclusion, in case that the fuse set 100_FS stores both of the multipurpose information and a part (e.g., in-the-bank address) of the failed address, since the in-the-bank address of the normal memory cells N3, N4 and N5 is same as the in-the-bank address of the failed memory cell, the repair operation is performed on those normal memory cells N3, N4 and N5. The second fuse circuit 120 for storing the other part (e.g., bank address) of the failed address of the failed memory cell may be used in storing the multipurpose in addition to the repair operation.

As described above, the repair fuse device in accordance with the embodiment of the present invention may store multipurpose information on all or a part of the fuse set instead of the failed address for the repair operation. Thus, the repair fuse device in accordance with the embodiment of the present invention may improve the efficiency of the fuse set which is not used for the repair operation and the efficiency of the net-die.

Moreover, since the repair fuse device in accordance with the embodiment of the present invention stores both of the multipurpose and a part of the failed address by partially separating the fuse set for storing one failed address, it is not necessary to add a fuse unit for storing the multipurpose information, and the repair operation may be performed using only the failed address stored on the part of the fuse set. Thus, the repair fuse device in accordance with the embodiment of the present invention may improve the efficiency of the fuse set and the efficiency of the net-die.

Moreover, since the repair fuse device in accordance with the embodiment of the present invention stores the multipurpose information on all or a part of the fuse set, the repair fuse device in accordance with the embodiment of the present invention may improve the efficiency of the fuse set and the efficiency of the net-die.

Also, since the repair fuse device in accordance with the embodiment of the present invention stores both of the multipurpose and a part of the failed address by partially separating the fuse set for storing one failed address, it is not necessary to add a fuse unit for storing the multipurpose information, and the repair operation may be performed using only the failed address stored on the part of the fuse set. Thus, the repair fuse device in accordance with the embodiment of the present invention may improve the efficiency of the fuse set and the efficiency of the net-die.

While the present invention has been described with respect to the specific embodiments, it will be apparent to those skilled in the art that various changes and modifications may be made without departing from the spirit and scope of the invention as defined in the following claims.

What is claimed is:

1. A fuse repair device, comprising:
a first fuse circuit configured to store a first portion out of a failed address;
a second fuse circuit configured to store a multipurpose information or a second portion of the failed address;
an enable control circuit configured to provide a first enable signal to enable the second fuse unit based on a first control signal;
a switch control circuit configured to provide a second enable signal to enable the second fuse unit based on a second control signal;
a repair control signal generation circuit configured to compare data stored in the first fuse circuit and the second fuse circuit with an input address, and generate a repair control signal based on the first enable signal and the second enable signal; and
a multipurpose control signal generation circuit configured to generate a multipurpose control signal to control operations different from a repair operation based on data stored in the second fuse circuit and the second control signal.

2. The fuse repair device of claim 1, wherein the second portion is a bank address of the failed address.

3. The fuse repair device of claim 1, wherein the multipurpose information includes a command set information, a mode register set information, and a test mode information.

4. The fuse repair device of claim 1, wherein each of the first fuse unit, the second fuse unit, the enable control circuit and the switch control circuit includes a fuse.

5. The fuse repair device of claim 1, wherein the repair control signal includes a normal control signal to inactivate a normal path when the redundant path is activated.

6. The fuse repair device of claim 5, wherein the redundant path is a redundant row path and the normal path is a normal row path.

7. The fuse repair device of claim 6, further comprising:
a redundant row decoder configured to activate the redundant row path in response to the repair control signal; and
a normal row decoder configured to inactivate the normal row path in response to the normal control signal.

8. The fuse repair device of claim 5, wherein the redundant path is a redundant column path and the normal path is a normal column path.

9. The fuse repair device of claim 8, further comprising:
a redundant column decoder configured to activate the redundant column path in response to the repair control signal; and
a normal column decoder configured to inactivate the normal column path in response to the normal control signal.

10. A fuse repair method, comprising:
storing a part of a failed address on a fuse circuit to store the failed address;
receiving an input address;
comparing the part of the failed address with a corresponding part of the input address, and activating a redundant path for a normal memory cell that is not identified with the part of the failed address based on a comparison result; and
exchanging the normal memory cell to the redundant cell by activating the redundant path.

11. The fuse repair method of claim 10, further comprising:
storing multipurpose information on the other part different from the part of the failed address on the fuse circuit.

12. The fuse repair method of claim 10, wherein the other part different from the part of the failed address is a bank address.

13. The fuse repair method of claim 10, further comprising:
inactivating the normal path when the redundant path is activated.
